(19) United States
(12) Patent Application Publication
(10) Pub. No.: US 2016/0055957 A1
(43) Pub. Date: Feb. 25, 2016

(54) COMMON MODE FILTER AND MANUFACTURING METHOD THEREOF

(71) Applicant: SAMSUNG ELECTRO-MECHANICS CO., LTD., Suwon-Si (KR)

(72) Inventors: Seung-Wook PARK, Suwon (KR); Won-Chul SIM, Seongnam (KR); Jong-Yun LEE, Incheon (KR)

(21) Appl. No.: 14/663,423

(22) Filed: Mar. 19, 2015

(30) Foreign Application Priority Data
Aug. 25, 2014 (KR) 10-2014-0110879

(51) Int. Cl. H01F 27/28; H01F 27/24; H03H 7/01; H01F 41/04

(52) U.S. Cl. CPC H01F 27/2804; H01F 41/041; H01F 27/24; H03H 7/01; H01F 2027/2809

(57) ABSTRACT

A common mode filter and a method of manufacturing the same are disclosed. The common mode filter in accordance with an aspect of the present invention includes: a substrate; a filter layer comprising a coil and an insulation layer and formed on the substrate to remove a signal noise; a magnetic compound layer laminated on the filter layer; an electrostatic electrode pattern formed on the magnetic compound layer to remove static electricity and having one portion thereof exposed to a lateral surface of the magnetic compound layer; a sealing layer laminated on the electrostatic electrode pattern so as to seal the electrostatic electrode pattern; and a lateral surface electrode connected with the exposed portion of the electrostatic electrode pattern and formed in a longitudinal direction between the sealing layer and the substrate.

### CROSS-REFERENCE TO RELATED APPLICATIONS

This application claims the benefit of Korean Patent Application No. 10-2014-0110879, filed with the Korean Intellectual Property Office on Aug. 25, 2014, the disclosure of which is incorporated herein by reference in its entirety.

### BACKGROUND

1. Technical Field

The present invention relates to a common mode filter and a manufacturing method thereof.

2. Background Art

With the recent technological advancement, a growing number of electronic devices, such as mobile phones, home electronic appliances, PCs, PDAs and LCDs, have been changed from analog systems to digital systems. Moreover, owing to the increased amount of processed data, the electronic devices are required to be faster.

As the electronic devices are digitized and become faster, the electronic devices can be increasingly sensitive to irritation from outside. That is, any small abnormal voltage or high-frequency noise brought into the internal circuitry of an electronic device from the outside can cause a damage to the circuitry or a distortion of signal.

Sources of the abnormal voltage and noise that cause the circuitry damage or signal distortion of the electronic device include lightning, discharging of static electricity that has been charged in human body, switching voltage generated in the circuitry, power noise included in the electric source voltage, unnecessary electromagnetic signal or electromagnetic noise, etc.

In order to prevent the circuitry damage or signal distortion of the electronic device, a filter needs to be installed to prevent the abnormal voltage and high-frequency noise from being brought into the circuitry. Particularly, a common mode filter is often installed in, for example, a high-speed differential signal line in order to remove common mode noise.

Meanwhile, in order to inhibit an electro static discharge (ESD) that may occur at input/output terminals in a general differential signal transmission system, a diode, a varistor and/or other passive components need to be used in addition to the common mode filter for removing the common mode noise.

Using the additional passive component in order to address the ESD issue causes an increase in installation area and a rise in production cost as well as a distortion of signal.

The related art of the present invention is disclosed in Korea Patent Publication No. 10-2012-0033644 (laid open on Apr. 9, 2012).

### SUMMARY

An embodiment of the present invention provides a common mode filter with a function of removing static electricity that has a filter layer, a magnetic compound layer, an electrostatic electrode pattern and a sealing layer laminated successively on a substrate and allows the electrostatic electrode pattern to be electrically connected in a longitudinal direction through a lateral surface electrode, and a method of manufacturing a common mode filter.

Here, the filter layer, the magnetic compound layer, the electrostatic electrode pattern and the sealing layer may be laminated and formed on one surface of a core, and the substrate may be bonded to a surface of the filter layer from which the core is removed.

### BRIEF DESCRIPTION OF DRAWINGS

FIG. 1 is a perspective view showing a common mode filter in accordance with an embodiment of the present invention.

FIG. 2 is a cross-sectional view showing the common mode filter in accordance with an embodiment of the present invention.

FIG. 3 is a flow diagram showing a method of manufacturing a common mode filter in accordance with an embodiment of the present invention.

FIG. 4, FIG. 5, FIG. 6, FIG. 7, FIG. 8, FIG. 9, FIG. 10 and FIG. 11 show main steps of the method of manufacturing a common mode filter in accordance with an embodiment of the present invention.

FIG. 12 is a cross-sectional view showing a common mode filter in accordance with another embodiment of the present invention.

### DETAILED DESCRIPTION

Hereinafter, certain embodiments of a common mode filter and a manufacturing method thereof in accordance with the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

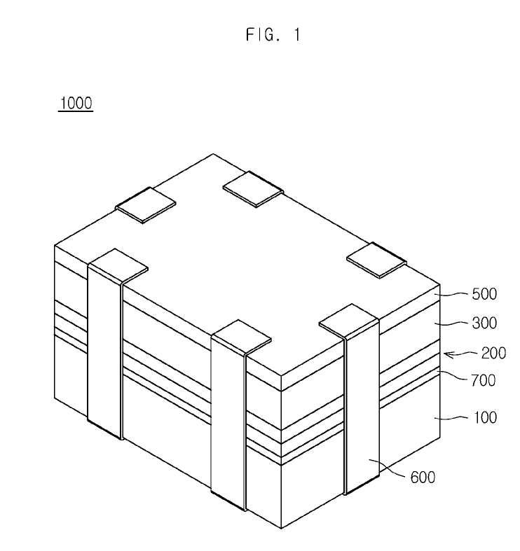

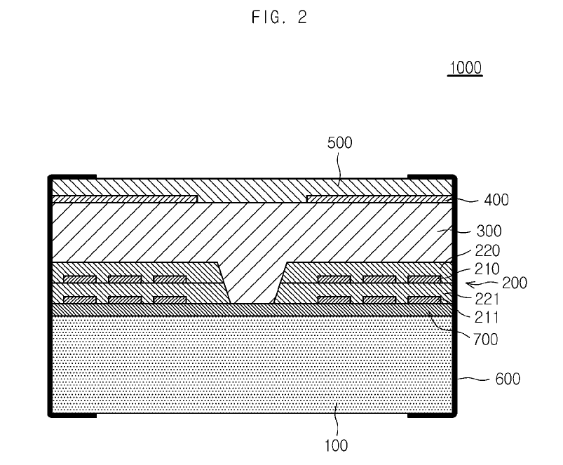

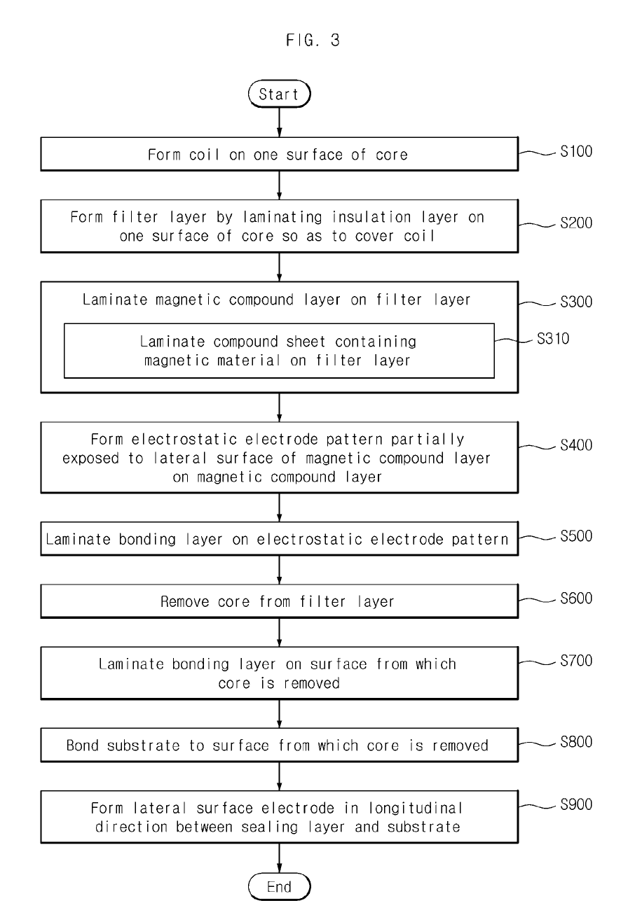

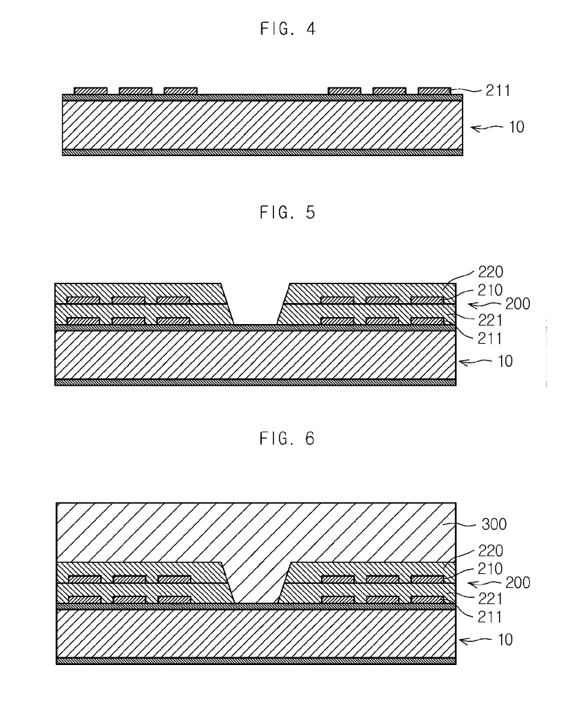

FIG. 1 is a perspective view showing a common mode filter in accordance with an embodiment of the present invention. FIG. 2 is a cross-sectional view showing the common mode filter in accordance with an embodiment of the present invention.

Referring to FIG. 1 and FIG. 2, a common mode filter 1000 in accordance with an embodiment of the present invention includes a substrate 100, a filter layer 200, a magnetic compound layer 300, an electrostatic electrode pattern 400, a sealing layer 500 and a lateral surface electrode 600, and may further include a bonding layer 700.

The substrate 100, which is a portion that supports the filter layer 200, may form a magnetic field with the magnetic compound layer 300. In such a case, the substrate 100 functions to support the filter layer 200 and may be disposed at a bottom portion of the common mode filter 1000 in accordance with the present embodiment.

Here, the substrate 100 may include a magnetic material and function as a closed magnetic circuit. For instance, the substrate 100 may include sintered ferrite or a ceramic material such as forsterite. The substrate 100 may be formed with a predetermined area or thickness according to the shape of the common mode filter 1000.

The filter layer 200 includes coils 210, 211 and insulation layers 220, 221 and is disposed on the substrate 100 to remove signal noises. As shown in FIG. 2, the filter layer 200 may include a plurality of insulation layers 220, 221 that are laminated and a plurality of coils 210, 211.

That is, the filter layer 200 may include a plurality of insulation layers 220, 221 that are successively laminated on an upper surface of the substrate 100 and a plurality of coils 210, 211 that are interposed between the insulation layers 220, 221. Here, the insulation layers 220, 221 may be made of different materials if necessary.

For instance, the insulation layer 221 formed at a portion that is in contact with the magnetic compound layer 300 may be formed by laminating a bonding compound sheet so as to facilitate the bonding with the magnetic compound layer 300.

The insulation layers 220, 221 may be formed by using polyimide, epoxy resin, benzocyclobutene (BCB) or any other polymer, or may be formed by using a photo via method or a laser via method. Here, the photo via method refers to a laminating method using a special developing ink added with insulation resin as the insulation layers 220, 221.

Moreover, as shown in FIG. 2, the insulation layers 220, 221 may have a cavity formed at a portion thereof and reinforce magnetic flux by filling in the cavity with a magnetic body, for example, the magnetic compound layer 300.

The coils 210, 211 in the filter layer 200 may be electrically connected with the lateral surface electrode 600 or a separate external terminal that is formed on a lateral surface or a top surface of the common mode filter 1000 in accordance with the present embodiment.

The magnetic compound layer 300, which is laminated on the filter layer 200, may form a magnetic field with the substrate 100. Moreover, together with the substrate 100, the magnetic compound layer 300 may protect the filter layer 200.

Particularly, in case the electrostatic electrode pattern 400 is laminated directly on the coils 210, 211, a loss of magnetic permeability may be occurred to lower the functionality of the common mode filter. Accordingly, the coils 210, 211 may be sealed by the magnetic compound layer 300, and the electrostatic electrode pattern 400 may be formed over the magnetic compound layer 300.

Meanwhile, as described above, in the case where the cavity is formed at a portion of the insulation layers 220, 221 of the filter layer 200, the magnetic compound layer 300 may be laminated on the filter layer 200 while filling in the cavity.

The electrostatic electrode pattern 400, which is formed on the magnetic compound layer 300 to remove static electricity and have one portion thereof exposed to a lateral surface of the magnetic compound layer 300, may absorb excessive voltage caused by occurrence of static electricity to inhibit an electro static discharge (ESD).

The electrostatic electrode pattern 400 may be made of a material in which an organic matter is mixed with at least one conductive material selected from the group consisting of TiO₂, RuO₂, Pt, Pd, Ag, Au, Ni, Cr, W, Cu and Al. Moreover, the electrostatic electrode pattern 400 may be formed in a predetermined pattern through a printing process using exposure and development.

In such a case, as shown in FIG. 2, the electrostatic electrode pattern 400 may have a portion thereof exposed to the lateral surface of the magnetic compound layer 300 so as to be electrically connected with the lateral surface electrode 600.

The sealing layer 500, which is laminated on the electrostatic electrode pattern 400 so as to seal the electrostatic electrode pattern 400, may fix and protect the electrostatic electrode pattern 400 by sealing the electrostatic electrode pattern 400. That is, the sealing layer 500 is a kind of solder resist layer for preventing the electrostatic electrode pattern 400 from being exposed and may form an uppermost surface of the common mode filter 1000 in accordance with the present embodiment shown in FIG. 2.

The lateral surface electrode 600, which is connected with a portion of the electrostatic electrode pattern 400 that is exposed to the lateral surface of the magnetic compound layer 300 to be formed in a longitudinal direction between the sealing layer 500 and the substrate 100, allows for electrical conduction between the top surface and a bottom surface of the common mode filter 1000 in accordance with the present embodiment.

In the common mode filter 1000 in accordance with the present embodiment, the electrostatic electrode pattern 400 is disposed in an upper portion thereof only. Accordingly, in order to electrically connect the electrostatic electrode pattern 400 with a lower portion thereof, a via or the like may need to be formed in the magnetic compound layer 300 and the substrate 100, and an additional grinding process may need to be introduced, resulting in an increase in manufacturing processes.

However, as described above, in the common mode filter 1000 in accordance with the present embodiment, electrical conduction is possible between the top and bottom surfaces thereof through the lateral surface electrode 600, and thus the manufacturing processes may be minimized, saving the processing cost and time.

In the common mode filter 1000 in accordance with the present embodiment, one portion of the electrostatic electrode pattern 400 may be exposed to a top surface of the sealing layer 500 by penetrating the sealing layer 500, and the exposed electrostatic electrode pattern 400 may be electrically connected with the lateral surface electrode 600.

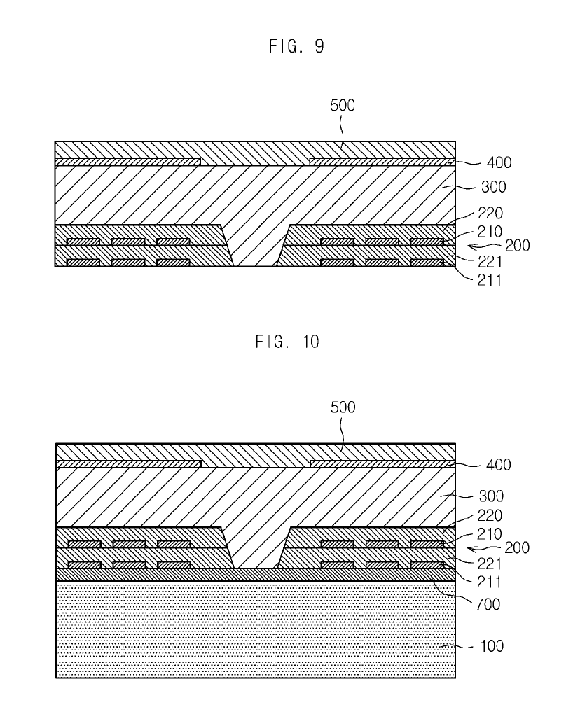

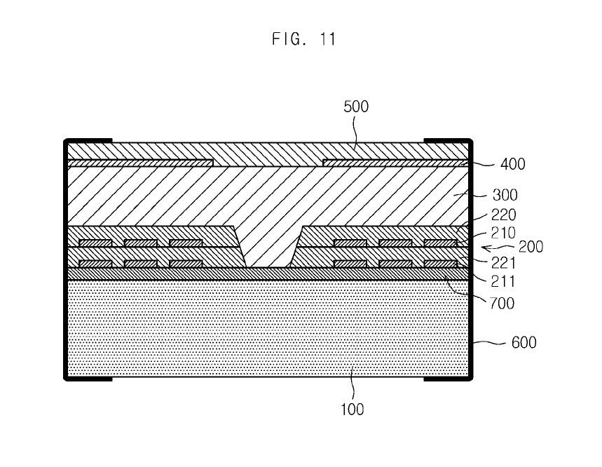

In the common mode filter 1000 in accordance with the present embodiment, the filter layer 200, the magnetic compound layer 300, the electrostatic electrode pattern 400 and the sealing layer 500 may be successively laminated and formed on one surface of a core 10 (shown in FIG. 4), and the substrate 100 may be bonded to a surface of the filter layer 200 from which the core 10 is removed.

In other words, the coils 210, 211 for removing signal noises may be formed by using the separate core 10 as a temporary carrier. Then, the core 10 may be removed after forming the electrostatic electrode pattern 400, which is for removing static electricity, on the filter layer 200 having the coils 210, 211 formed thereon. Then, by bonding the substrate 100 on the surface from which the core 10 is removed, the common mode filter 1000 having the structure shown in FIG. 1 and FIG. 2 may be formed.

When a conventional thin-type common mode filter is manufactured, rather costly processes of sputtering, plating, grinding and inter-layer alignment need to be introduced in order to form a filter layer, thereby relatively increasing the processing cost and time.

However, with the common mode filter 1000 in accordance with the present embodiment, the metallic, coil layers 210, 211 are formed on the separate core 10, like in general multi-layer printed circuit boards, eliminating the need for an alignment process, which is commonly introduced in a manufacturing process of the conventional thin-type common mode filter. Moreover, since the magnetic compound layer 300 may be laminated as in the manufacturing process of the general multi-layer printed circuit boards, the relevant processes may be minimized.

The bonding layer 700, which is interposed between the substrate 100 and the filter layer 200 for bonding of the substrate 100 and the filter layer 200 with each other, may provide a flat bonding surface and a tighter adhesion.

The bonding layer 700 may be formed by using polyimide, epoxy resin, benzocyclobutene (BCB) or any other polymer and have an impedance thereof adjusted by adjusting a thickness thereof using, for example, a spin coating layer, lamination, slit die coating, etc.

Moreover, the bonding layer 700 may be configured to improve the functionality of the common mode filter 1000 by, for example, enhancing a magnetic flux by using a magnetically-permeable material.

In the case where the magnetic compound layer 300 is formed with a compound sheet containing a magnetic material, the common mode filter 1000 in accordance with the present embodiment may be manufactured more effectively. For example, the magnetic compound layer 300 may be a sheet structure formed with an epoxy resin containing ferrite powder.

Since attaching the compound sheet on a top surface of the filter layer 200 is sufficient for the common mode filter 1000 in accordance with the present embodiment, without a complicated process of coating or filling the magnetic compound layer 300 on or in the filter layer 200, the common mode filter 1000 may be manufactured more readily.

The magnetic compound layer 300 may be substituted with the insulation layer 220, 221, or may be formed with a paste.

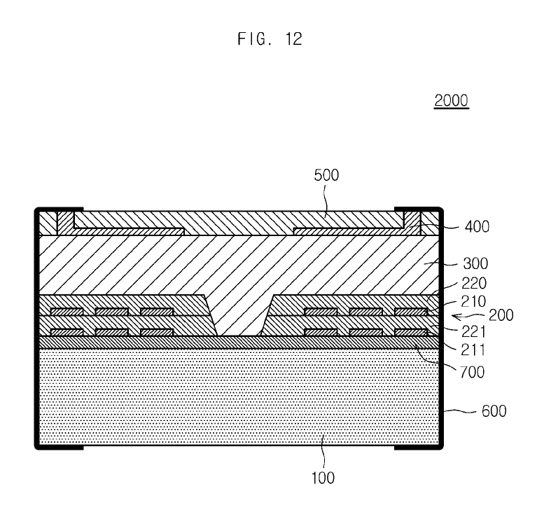

FIG. 12 is a cross-sectional view showing a common mode filter in accordance with another embodiment of the present invention.

As illustrated in FIG. 12, a common mode filter 2000 in accordance with another embodiment of the present invention includes a substrate 100, a filter layer 200, a magnetic compound layer 300, an electrostatic electrode pattern 400, a sealing layer 500 and a lateral surface electrode 600, and may further include a bonding layer 700.

Particularly, as shown in FIG. 12, in the common mode filter 2000 in accordance with the present embodiment, the sealing layer 500 is laminated on the electrostatic electrode pattern 400 so as to seal the electrostatic electrode pattern 400, and a portion of the sealing layer 500 is penetrated by the electrostatic electrode pattern 400 in such a way that a portion of the electrostatic electrode pattern 400 is exposed.

The lateral surface electrode 600 is connected with the exposed portion of the electrostatic electrode pattern 400 that is exposed through the sealing layer 500, as described above, and is formed in a longitudinal direction between the sealing layer 500 and the substrate 100.

In other words, a portion of the electrostatic electrode pattern 400 is exposed to the top surface of the common mode filter 2000, and the electrostatic electrode pattern 400 that is exposed to the top surface may be electrically connected with the lateral surface electrode 600.

Accordingly, the common mode filter 2000 in accordance with another embodiment of the present invention may also minimize the formation of additional vias or the like and thus minimize the manufacturing processes, saving the processing cost and time.

Except for the above-described elements, most elements of the common mode filter 2000 in accordance with another embodiment of the present invention are identical or similar to those of the common mode filter 1000 in accordance with an embodiment of the present invention, and thus any redundant description will not be provided herein.

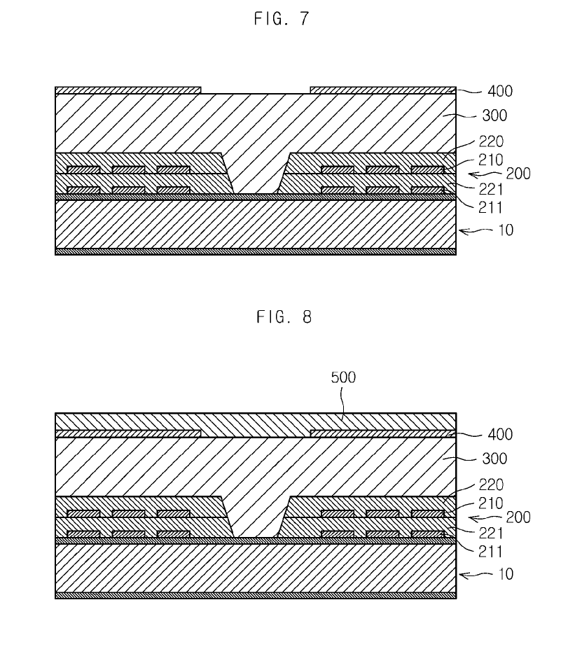

FIG. 3 is a flow diagram showing a method of manufacturing a common mode filter in accordance with an embodiment of the present invention. FIG. 4, FIG. 5, FIG. 6, FIG. 7, FIG. 8, FIG. 9, FIG. 10 and FIG. 11 show main steps of the method of manufacturing a common mode filter in accordance with an embodiment of the present invention.

As shown in FIG. 3 to FIG. 11, the method of manufacturing a common mode filter in accordance with an embodiment of the present invention starts with forming a coil 211 on one surface of a core 10 (S100, FIG. 4).

In such a case, the coil 211 may be formed by plating a conductive layer on the core 10 and then patterning the conductive layer.

Then, a filter layer 200 is formed by laminating an insulation layer 221 on one surface of the core 10 so as to cover the coil 211 (S200, FIG. 5). In such a case, the filter layer 200 may include a plurality of insulation layers 220, 221 that are successively laminated on a top surface of the core 10 and a plurality of coils 210, 211 that are interposed between the insulation layers 220, 221.

Here, the insulation layers 220, 221 may be made of different materials if necessary. For instance, the insulation layer 221 formed at a portion that is in contact with a magnetic compound layer 300 may be formed by laminating a bonding compound sheet so as to facilitate the bonding with the magnetic compound layer 300.

Moreover, as shown in FIG. 5, the insulation layers 220, 221 may have a cavity formed at a portion thereof and reinforce magnetic flux by filling in the cavity with a magnetic body, for example, the magnetic compound layer 300.

Next, the magnetic compound layer 300 is laminated on the filter layer 200 (S300, FIG. 6). In such a case, the magnetic compound layer 300 may form a magnetic field, together with a substrate 100. Moreover, the magnetic compound layer 300 may protect the filter layer 200, together with the substrate 100.

Particularly, in case an electrostatic electrode pattern 400 is laminated directly on the coils 210, 211, a loss of magnetic permeability may be occurred to lower the functionality of the common mode filter. Accordingly, the coils 210, 211 may be sealed by the magnetic compound layer 300, and the electrostatic electrode pattern 400 may be formed over the magnetic compound layer 300.

Then, the electrostatic electrode pattern 400 having one portion thereof exposed to a lateral surface of the magnetic compound layer 300 is formed on the magnetic compound layer 300 (S400, FIG. 7). In such a case, the electrostatic electrode pattern 400 may absorb excessive voltage caused by occurrence of static electricity to inhibit an electro static discharge (ESD).

The electrostatic electrode pattern 400 may be exposed to the lateral surface of the magnetic compound layer 300 to be electrically connected with the lateral surface electrode 600.

Then, a sealing layer 500 is laminated on the electrostatic electrode pattern 400 (S500, FIG. 8). Here, the sealing layer 500 is laminated on the electrostatic electrode pattern 400 so as to seal the electrostatic electrode pattern 400 and may fix and protect the electrostatic electrode pattern 400 by sealing the electrostatic electrode pattern 400.

That is, the sealing layer 500 is a kind of solder resist layer for preventing the electrostatic electrode pattern 400 from being exposed and may form an uppermost surface of the common mode filter 1000 in accordance with the present embodiment.

Afterwards, the core 10 may be removed from the filter layer 200 (S600, FIG. 9). In such a case, the core 10 may be removed from the filter layer 200 through, for example, a routing process. As a result, one surface of the filter layer 200 may be exposed.

Thereafter, the substrate 100 may be bonded to a surface of the filter layer 200 from which the core 10 is removed (S800, FIG. 10). That is, when the common mode filter 1000 is manufactured, the filter layer 200, the magnetic compound layer 300, the electrostatic electrode pattern 400 and the sealing layer 500 may be successively laminated and formed on the separate core 10, and then the substrate 100 may be bonded after the core 10 is ultimately removed.

As such, with the method of manufacturing a common mode filter in accordance with the present embodiment, the metallic, coil layers 210, 211 are formed on the separate core 10, like in the method of manufacturing a general multi-layer printed circuit board, eliminating the need for an alignment process, which is commonly introduced in a manufacturing process of the conventional thin-type common mode filter. Moreover, since the magnetic compound layer 300 may be laminated as in the manufacturing process of the general multi-layer printed circuit board, the relevant processes may be minimized.

In the method of manufacturing a common mode filter in accordance with the present embodiment, a lateral surface electrode 600 that is connected with the portion of the electrostatic electrode pattern 400 that is exposed to the lateral surface of the magnetic compound layer 300 may be formed in a longitudinal direction between the sealing layer 500 and the substrate 100 (S900, FIG. 11).

As a result, the lateral surface electrode 600 may allow for electrical conduction between a top surface and a bottom surface of the common mode filter 1000.

In the common mode filter 1000 in accordance with the present embodiment, the electrostatic electrode pattern 400 is disposed in an upper portion thereof only. Accordingly, in order to electrically connect the electrostatic electrode pattern 400 with a lower portion thereof, a via or the like may need to be formed in the magnetic compound layer 300 and the substrate 100, and an additional grinding process may need to be introduced, resulting in an increase in manufacturing processes.

However, as described above, in the method of manufacturing a common mode filter in accordance with the present embodiment, electrical conduction is possible between the top and bottom surfaces of the common mode filter 1000 through the lateral surface electrode 600, and thus the manufacturing processes may be minimized, saving the processing cost and time.

The method of manufacturing a common mode filter in accordance with the present embodiment may further include, between the S600 step and the S800 step, laminating a bonding layer 700 on a surface of the filter layer 200 from which the core 10 is removed (S700).

In such a case, the bonding layer 700 may be interposed between the substrate 100 and the filter layer to provide a flat bonding surface and a tighter adhesion. Moreover, the bonding layer 700 may be configured to improve the functionality of the common mode filter 1000 by, for example, enhancing a magnetic flux by using a magnetically-permeable material.

In the method of manufacturing a common mode filter in accordance with the present embodiment, the S300 step may include laminating a compound sheet containing a magnetic material on the filter layer 200 (S310). For example, the magnetic compound layer 300 may be a sheet structure formed with an epoxy resin containing ferrite powder.

Since attaching the compound sheet on a top surface of the filter layer 200 is sufficient for the method of manufacturing a common mode filter in accordance with the present embodiment, without a complicated process of coating or filling the magnetic compound layer 300 on or in the filter layer 200, the common mode filter 1000 may be manufactured more readily.

Meanwhile in the method of manufacturing a common mode filter in accordance with an embodiment of the present invention, the main elements of the common mode filter 1000 in accordance with an embodiment of the present invention have been already described above, any redundant description will not be provided herein.

Although certain embodiments of the present invention have been described, it shall be appreciated that there can be a very large number of permutations and modification of the present invention by those who are ordinarily skilled in the art to which the present invention pertains without departing from the technical ideas and scope of the present invention, which shall be defined by the claims appended below. It shall be also appreciated that many other embodiments than the embodiments described above are included in the claims of the present invention.

1. A common mode filter comprising:
a substrate;
a filter layer comprising a coil and an insulation layer and formed on the substrate to remove a signal noise;
a magnetic compound layer laminated on the filter layer;
an electrostatic electrode pattern formed on the magnetic compound layer to remove static electricity and having one portion thereof exposed to a lateral surface of the magnetic compound layer;
a sealing layer laminated on the electrostatic electrode pattern so as to seal the electrostatic electrode pattern; and
a lateral surface electrode connected with the exposed portion of the electrostatic electrode pattern and formed in a longitudinal direction between the sealing layer and the substrate.

2. The common mode filter of claim 1, wherein the filter layer, the magnetic compound layer, the electrostatic electrode pattern and the sealing layer are successively laminated and formed on one surface of a core, and
wherein the substrate is bonded to a surface of the filter layer from which the core is removed.

3. The common mode filter of claim 2, further comprising a bonding layer interposed between the substrate and the filter layer so as to allow the substrate and the filter layer to be bonded with each other.

4. The common mode filter of claim 1, wherein the magnetic compound layer is formed with a compound sheet containing a magnetic material.

5. A common mode filter comprising:
a substrate;
a filter layer comprising a coil and an insulation layer and formed on the substrate to remove a signal noise;
a magnetic compound layer laminated on the filter layer;
an electrostatic electrode pattern formed on the magnetic compound layer to remove static electricity;
a sealing layer laminated on the electrostatic electrode pattern so as to seal the electrostatic electrode pattern and having a portion thereof penetrated by the electrostatic electrode pattern so as to allow a portion of the electrostatic electrode pattern to be exposed; and
a lateral surface electrode connected with the exposed portion of the electrostatic electrode pattern and formed in a longitudinal direction between the sealing layer and the substrate.

6. A method of forming a common mode filter, comprising:
forming a coil on one surface of a core;
forming a filter layer by laminating an insulation layer on the one surface of the core so as to cover the coil;
laminating a magnetic compound layer on the filter layer;
forming an electrostatic electrode pattern having one portion thereof exposed to a lateral surface of the magnetic compound layer on the magnetic compound layer;
laminating a sealing layer on the electrostatic electrode pattern;
removing the core from the filter layer; and
bonding a substrate to a surface of the filter layer from which the core is removed.

7. The method of claim 6 further comprising, after the bonding of the substrate, forming a lateral surface electrode being connected with the exposed portion of the electrostatic electrode pattern in a longitudinal direction between the sealing layer and the substrate.

8. The method of claim 7, further comprising, between the removing of the core and the bonding of the substrate, laminating a bonding layer on a surface of the filter layer from which the core is removed.

9. The method of claim 6, wherein the laminating of the magnetic compound layer comprises laminating a compound sheet containing a magnetic material on the filter layer.
